(19) United States
(12) Patent Application Publication
(10) Pub. No.: US 2014/0316735 A1
(43) Pub. Date: Oct. 23, 2014

(54) Protection Device and Calibration Method Thereof

(71) Applicants: Tong-Cheng Jao, Taichung (TW); Isaac Y. Chen, Zhubei City (TW)

(72) Inventors: Tong-Cheng Jao, Taichung (TW); Isaac Y. Chen, Zhubei City (TW)

(73) Assignee: RICHTEK TECHNOLOGY CORPORATION, Zhubei City (TW)

(21) Appl. No.: 14/153,804

(22) Filed: Jan. 13, 2014

(30) Foreign Application Priority Data
Apr. 22, 2013 (TW) 102114119

(51) Int. Cl. G01R 35/00

(52) U.S. Cl. CPC G01R 35/005
USPC 702/107

(57) ABSTRACT

The present invention discloses a protection device and a calibration method thereof. The protection device includes a sensing circuit and a detection circuit. The detection circuit includes: a comparing circuit, a setting circuit and an automatic calibration circuit. The comparing circuit is coupled to the sensing circuit and generates a protection signal according to a sensing signal and an offset setting. The setting circuit is coupled to the comparing circuit and generates the offset setting according to a calibration signal. The automatic calibration circuit is coupled between the comparing circuit and the setting circuit, for generating the calibration signal. The automatic calibration circuit automatically sets a protection threshold and stores the calibration signal which corresponds to the protection threshold.

### CROSS REFERENCE

The present invention claims priority to TW 102114119, filed on Apr. 22, 2013.

### BACKGROUND OF THE INVENTION

1. Field of Invention

The present invention relates to a protection device and a calibration method of a protection device; particularly, it relates to such protection device and calibration method, which do not require manual calibration and can be applied to, for example but not limited to, over current protection.

2. Description of Related Art

FIG. 1 shows a schematic diagram of a conventional over current protection device 100. As shown in FIG. 1, the over current protection device 100 comprises a current sensing circuit 110 and an over current sensing circuit 120. The current sensing circuit 110, which can be for example a resistor, senses a current Iout which is to be monitored. The over current sensing circuit 120 comprises a comparator circuit 130, a setting circuit 140 and a pre-set circuit 150. The pre-set circuit 150 determines a predetermined current threshold which can be set according to a reference signal Vref and a setting resistor Rset. The comparator circuit 130 compares the current Iout with the predetermined current threshold, and generates an over current protection signal OCP indicating an over current status when the current Iout exceeds the predetermined current threshold. Because the predetermined current threshold determined by the pre-set circuit 150 may be inaccurate due to its internal device mismatch or other errors, the over current sensing circuit 120 comprises the setting circuit 140 which is a manual calibration circuit for calibrating the predetermined current threshold. The setting circuit 140 comprises a variable resistor VR whose resistance can be manually adjusted after the over current protection device 100 has been manufactured, so that the errors in the circuit can be corrected and the over current protection signal OCP can be accurately generated by the over current protection device 100.

For example, according to the Advanced Technology Extended (ATX) specification, an over current protection signal OCP must be generated before the current Iout exceeds 20 A. Generally, a typical over current protection device 100 is designed to generate an over current protection signal OCP when the current Iout exceeds a magnitude of 19+/−0.5 A. However, because of the mismatch or other errors of the circuit devices resulting from the manufacturing process or other causes, the over current protection device 100 may not precisely generate the over current protection signal OCP at the above-mentioned set value. As a consequence, after the over current protection device 100 has been manufactured, it is required to adjust the resistance of the variable resistor VR included in the setting circuit 140 to calibrate the over current protection device 100, so that the over current protection device 100 complies with the requirement set forth in the ATX specification.

However, to manually adjust the resistance of the variable resistor VR is labor-consuming and the cost of the variable resistor VR is high, so the conventional over current protection device 100 is ineffective. Taiwan Patent Application No. TW 100103237 proposes a circuit capable of setting the over current protection threshold. This application, however, simply discloses an abstract idea, but does not demonstrate how the hardware should be implemented to carry out an automatic calibration for the over current protection threshold. What this application discloses is, in fact, not different from the manual calibration. In view of the above, to overcome the drawbacks in the prior art, the present invention proposes a protection device with the clear disclosure of a hardware circuit, to provide the function of automatically calibrating the protection threshold. Such protection threshold can be set for, for example but not limited to, over current protection and over voltage protection. The present invention also provides a calibration method.

### SUMMARY OF THE INVENTION

From one perspective, the present invention provides a protection device, comprising: a sensing circuit for sensing a current signal or a voltage signal to generate a sensing signal; and a detection circuit coupled to the sensing circuit, for generating a protection signal according to the sensing signal, the detection circuit including: a comparing circuit coupled to the sensing circuit, for generating the protection signal according to the sensing signal and an offset setting; a setting circuit coupled to the comparing circuit, for generating the offset setting according to a calibration signal; and an automatic calibration circuit coupled between the comparing circuit and the setting circuit, for generating the calibration signal; wherein during a calibration process, the automatic calibration circuit generates and stores the calibration signal in digital form in correspondence to a protection threshold related to the current signal or the voltage signal, and under a normal operation, the comparing circuit compares the current signal or the voltage signal with the calibrated protection threshold.

In one embodiment, the automatic calibration circuit includes: a control circuit for generating a control signal according to the protection signal during the calibration process; a digital number generation circuit coupled to the control circuit, for generating a check signal and a write signal according to the control signal, wherein the check signal is used as the calibration signal during the calibration process; a memory circuit coupled to the digital number generation circuit, for storing the write signal outputted from the digital number generation circuit; and a multiplexer circuit coupled to the digital number generation circuit and the memory circuit, for selecting the check signal as the calibration signal during the calibration process and selecting a read signal outputted from the memory circuit as the calibration signal under the normal operation.

In one embodiment, the setting circuit includes: a current source circuit for generating a setting current signal; a current mirror circuit coupled to the current source circuit, for duplicating the setting current signal to a duplicated current signal which is proportional to the setting current signal; and a current to voltage circuit for converting the duplicated current signal to the offset setting; wherein the setting current signal is adjustable, or the ratio of the duplicated current signal to the setting current signal is adjustable, or a conversion ratio of the current to voltage circuit is adjustable, or two or more of the above are adjustable.

In one embodiment, the automatic calibration circuit further includes a trigger circuit for receiving a trigger signal and generating a confirmation signal in response to the trigger signal, to initiate the calibration process.

In one embodiment, the memory circuit includes a writable or a rewritable nonvolatile memory circuit.

From another perspective, the present invention provides a calibration method of a protection device, wherein the protection device is for comparing a signal to be monitored with a protection threshold to generate a judgment signal, the calibration method comprising the steps of: (1) providing a current signal or a voltage signal which corresponds to the protection threshold; (2) generating a check signal; (3) generating a calibration signal according to the check signal and generating an offset setting according to the calibration signal; (4) generating the judgment signal according to a comparison result between the offset setting and the current signal or the voltage signal; and (5) writing a digital number into a memory circuit according to a status indicated by the judgment signal.

In one embodiment, the calibration method further comprises: generating a flag signal to indicate that the calibration is finished.

In one embodiment, the calibration method further comprises: confirming whether the memory circuit is blank before generating the check signal; and when the memory circuit is not blank, erasing the data stored in the memory circuit.

In one embodiment, the calibration method further comprises: repeating the steps (2) to (5) to write multiple digital numbers into the memory circuit, wherein each digital number is one bit of a multi-bit data.

In one embodiment, the multi-bit data is written into the memory circuit from a most significant bit (MSB) to a least significant bit (LSB).

In one embodiment, the calibration method further comprises: before generating the check signal, confirming that a calibration process is initiated according to a trigger signal.

In one embodiment, the step of confirming that a calibration process is initiated according to the trigger signal includes: confirming whether the calibration process is initiated according to a level of the trigger signal or according to whether the trigger signal lasts for a predetermined time period.

The objectives, technical details, features, and effects of the present invention will be better understood with regard to the detailed description of the embodiments below, with reference to the attached drawings.

### BRIEF DESCRIPTION OF THE DRAWINGS

FIG. 1 shows a schematic diagram of a conventional over current protection device 100.

FIG. 2 shows a schematic diagram of a protection device according to a first embodiment of the present invention.

FIG. 3 shows a second embodiment of the present invention.

FIG. 4 shows the signal wave forms of the over current protection device during the calibration process.

FIG. 5 shows a third embodiment of the present invention.

FIG. 6 shows a fourth embodiment of the present invention.

FIG. 7 shows a fifth embodiment of the present invention.

FIG. 8 shows a sixth embodiment of the present invention.

FIG. 9 shows a seventh embodiment of the present invention.

FIG. 10 shows an eighth embodiment of the present invention.

### DESCRIPTION OF THE PREFERRED EMBODIMENTS

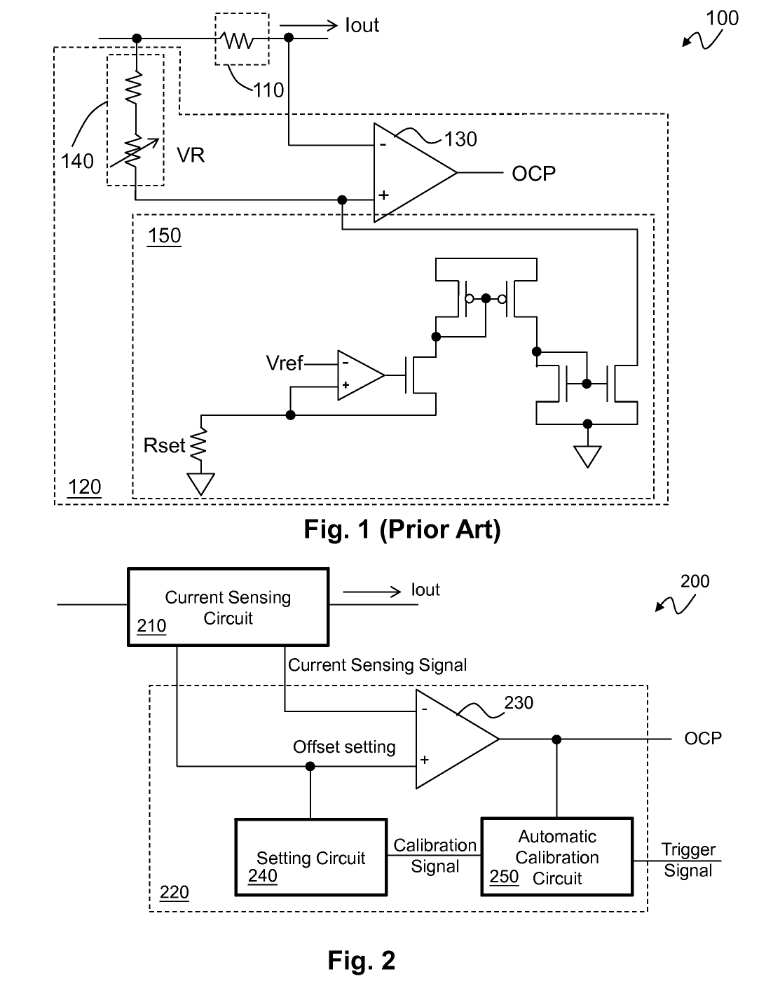

The present invention can be applied to all types of protection devices and is adapted for automatically setting the protection threshold in these protection devices. The present invention will be explained in detail by taking an application in over current protection as an example, but certainly, the present invention can also be applied in over voltage protection, under voltage protection or any other types of protection. Please refer to FIG. 2, which shows a schematic diagram of a protection device according to a first embodiment of the present invention. This embodiment illustrates a first circuit configuration wherein the present invention is applied to over current protection. As shown in FIG. 2, the protection device 200 (which may be used in an application circuit) comprises a current sensing circuit 210 and a detection circuit 220. The current sensing circuit 210 senses a current signal Iout which is to be monitored, and generates a current sensing signal corresponding to the current signal Iout. The detection circuit 220 is coupled to the current sensing circuit 210 and generates an over current protection signal OCP according to the current sensing signal. The detection circuit 220 includes a comparing circuit 230, a setting circuit 240 and an automatic calibration circuit 250. The comparing circuit 230 generates the over current protection signal OCP according to the current sensing signal and an offset setting. The setting circuit 240 is coupled to the comparing circuit 230 and generates the offset setting according to a calibration signal. The automatic calibration circuit 250 is coupled between the comparing circuit 230 and the setting circuit 240, for generating the calibration signal. The present invention is different from the prior art in that the automatic calibration circuit 250 can automatically calibrate the offset setting generated by the setting circuit 240.

In the above-mentioned embodiment, preferably, the automatic calibration circuit 250 initiates a calibration process according to a trigger signal. During the calibration process, first, a current Iout is provided to flow through the current sensing circuit 210. The provided current Iout has a magnitude which corresponds to a desired over current protection threshold, for example but not limited to, 19 A or 19.5 A according to the ATX specification. Next, the automatic calibration circuit 250 and the setting circuit 240 perform automatic calibration. That is, in response to the over current protection signal OCP outputted by the comparing circuit 230, and according to the information whether the over current protection signal OCP is indicative of or not indicative of an over current status, the internal setting of the setting circuit 240 is correspondingly adjusted until the over current protection signal OCP outputted by the comparing circuit 230 exactly indicates an over current status. Thus, the offset setting generated by the setting circuit 240 will be an accurate value, so that in normal operation of the application circuit, the comparing circuit 230 can correctly generate the over current protection signal OCP when the current Iout exceeds a predetermined current level.

The above explains the basic concept of the present invention; more details as to the hardware circuitry and the method steps of the present invention will be explained by embodiments later. The calibration process of the present invention does not require manual calibration. Besides, the calibration signal generated in the present invention can be stored in an internal memory circuit of the application circuit, so that, during normal operation of the application circuit, the protection device 200 can read out the data stored in the memory circuit to obtain the calibration signal. In addition, the accuracy of the calibration is determined by the circuit, so the calibration result of the present invention is far more accurate than the manual calibration of the prior art (manual calibration tends to be less accurate). Furthermore, the calibration process of the present invention can be performed during a full load condition of the application circuit; therefore, the bandgap temperature coefficient and other factors of the application circuit have been taken into consideration in the calibration process, so that the over current protection device of the present invention will operate more accurately in actual operation of the application circuit. Moreover, as compared with the manual calibration of the prior art, it takes much shorter time in the present invention to perform the calibration process. All of the above are the advantages of the present invention over the prior art.

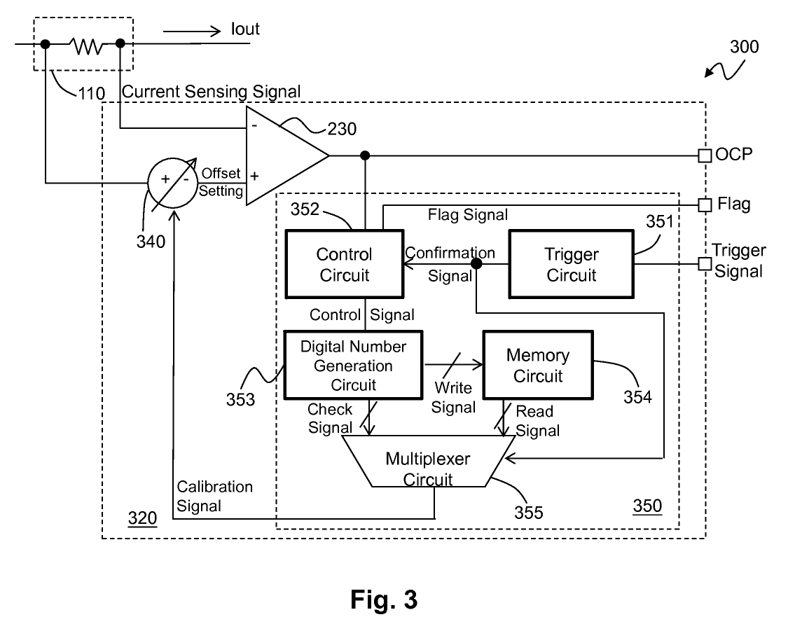

FIG. 3 shows a second embodiment of the present invention. As shown in FIG. 3, the protection device 300 comprises a current sensing circuit 110 and a detection circuit 320. The current sensing circuit 110 includes, for example but not limited to, a resistor through which the current Iout flows. The voltage drop across the resistor is regarded as a current sensing signal and is inputted to one terminal of a comparing circuit 230 included in the detection circuit 320. As shown in FIG. 3, the detection circuit 320 comprises the comparing circuit 230, a setting circuit 340 and an automatic calibration circuit 350. The setting circuit 340 comprises, for example, an offset voltage source whose voltage offset can be set by a calibration signal. An offset setting provided from the setting circuit 340 is inputted to the comparing circuit 230, whereby the comparing circuit 230 compares the current sensing signal with the offset setting to generate an over current protection signal OCP. Note that because, generally, there is an internal offset between the two terminals of the comparing circuit 230, the offset voltage source is not necessarily an external device of the comparing circuit 230. That is, the calibration signal can be adopted to set such internal offset, and in this case, this internal offset can be regarded as the setting circuit 340.

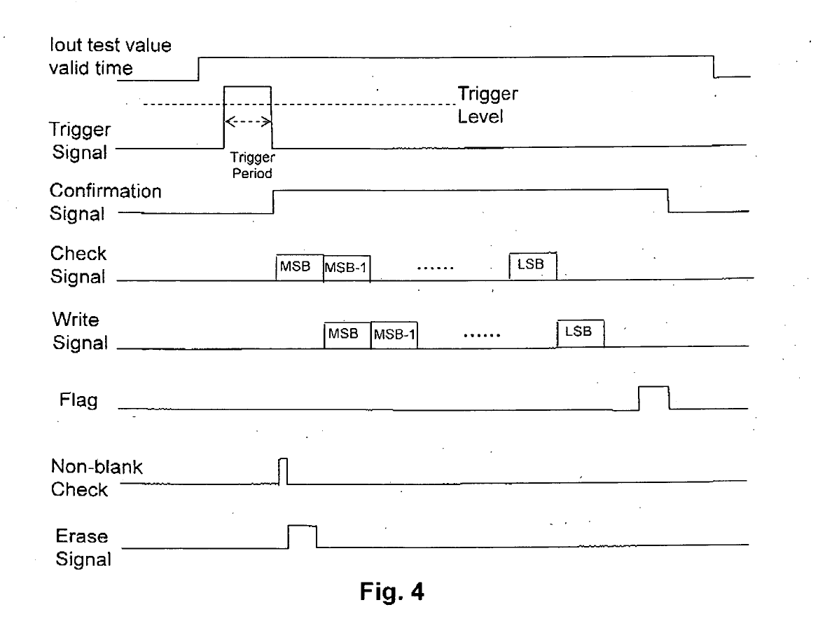

In this embodiment, the automatic calibration circuit 350 initiates the calibration process according to a trigger signal. The calibration process writes and stores an appropriate number into a memory circuit 354 through a comparison-and-writing process, whose details will be discussed later. The automatic calibration circuit 350 comprises a trigger circuit 351, a control circuit 352, a digital number generation circuit 353, a memory circuit 354 and a multiplexer circuit 355. The trigger circuit 351 generates a confirmation signal according to a trigger signal, to confirm that the calibration process should start. As to how the trigger circuit 351 generates the confirmation signal, two examples are shown by the wave forms of the trigger signal in FIG. 4. For one example, the confirmation signal can be generated when the trigger signal exceeds a trigger level (as shown by the trigger level in FIG. 4). Or, for another example, the confirmation signal can be generated when the trigger signal lasts for a predetermined time period (as shown by the trigger period of time in FIG. 4).

Please refer to FIG. 3 again. The control circuit 352 is coupled to the trigger circuit 351 and the comparing circuit 230. When the control circuit 352 receives the confirmation signal, it initiates the calibration process. The control circuit 352 generates a control signal according to an over current protection signal OCP during the calibration process. The digital number generation circuit 353 is coupled to the control circuit 352; it generates a number as a check signal according to the control signal. During the calibration process, the confirmation signal controls the multiplexer circuit 355 to select the check signal outputted by the digital number generation circuit 353 as a calibration signal, for adjusting the offset setting of the setting circuit 340. The comparing circuit 230 compares this offset setting with the current Iout, and the comparison result is inputted to the control circuit 352. According to this comparison result, the control signal generated by the control circuit 352 controls the digital number generation circuit 353 to write an appropriate number (write signal) into the memory circuit 354, wherein this written number is the appropriate number for an accurate calibration. After the calibration process ends, the control circuit 352 outputs a flag signal, which indicates that the calibration process is finished. After that, under a normal operation, the trigger signal no longer works and thus the confirmation signal is not generated, so the multiplexer circuit 355 selects the read signal outputted from the memory circuit 354 as the calibration signal.

Please refer to FIG. 3 in conjugation with FIG. 4, wherein FIG. 4 shows the signal wave forms during the calibration process. As shown in FIG. 4, first, a current signal Iout corresponding to the over current protection threshold is provided (the current signal Iout can start to be provided before or after entering the calibration process). Next, a trigger signal is provided, so that the trigger circuit 351 generates the confirmation signal to initiate the calibration process. As the over current protection device enters the calibration process, in one embodiment, it preferable to first check whether the memory circuit 354 is blank or not. If the memory circuit 354 is blank, the calibration process can go on. If the memory circuit 354 is not blank, the calibration process can be ended, or as shown in FIG. 4, the data stored in the memory circuit 354 can be erased first. Certainly, this memory check-and-erase step can be omitted. Next, or at the same time as the aforementioned memory check-and-erase step is carried out, the digital number generation circuit 353 can generate the check signal. In one embodiment, the digital number generation circuit 353 first generates a number for the most significant bit (MSB). This number is outputted through the multiplexer circuit as the calibration signal to adjust the setting circuit 340 correspondingly, and the comparing circuit 230 generates a corresponding comparison result accordingly. The control signal controls the digital number generation circuit 353 according to the comparison result, to write an appropriate number of the MSB into the memory circuit 354, as shown by the “write signal” in FIG. 4. Next, or at the same time, the digital number generation circuit 353 can generate a number for the next most significant bit (MSB-1), and the similar steps described above are repeated, until the number of the least significant bit (LSB) is written into the memory circuit 340. Thereafter, the control circuit 352 outputs a flag signal Flag, which indicates that the calibration process is finished.

More specifically, the over current protection threshold desired to be set (e.g., 19.5 A according to the ATX specification) is an analog number. The offset setting generated by the setting circuit 340 can be adjusted within a certain range of this analog number. The calibration signal is a digital signal having a number of bits, and the number of the bits (i.e., the length or size of the digital signal) can be determined according to the desired accuracy. The value of the calibration signal expressed by a digital number of plural bits determines an adjustment amount of the offset setting. The offset setting corresponding to the current Iout can be obtained during the calibration process; for example, if the current Iout given during the calibration process is 19.5 A, the offset setting corresponding to 19.5 A can be obtained. And, the digital number of the calibration signal corresponding to this offset setting is written into the memory circuit 354 to be stored. Because the number is stored in a form of digital data, it can be preserved accurately, for generating an accurate over current protection threshold under normal operation.

Moreover, in a preferred embodiment of the present invention, the calibration process first determines the most significant bit (MSB) of the calibration signal, then the next most significant bit (MSB-1) of the calibration signal, then the next, until the least significant bit (LSB) of the calibration signal. This method has the following advantage. For example, assuming that the calibration signal has eight bits, the calibration process can be completed by eight comparison steps. Under the same assumption that the calibration signal has eight bits, it takes longer to complete the calibration process if the calibration process starts the comparison from the greatest value in a top-down manner (i.e., 11111111→11111110→11111101→ . . . ), or from the smallest value in a bottom-up manner (i.e., 00000000→00000001→00000010→ . . . ). Besides, preferably, the calibration process should be performed in a pipeline manner; that is, the comparison for determining a next bit starts at the same time as a preceding bit is written into the memory circuit 340, to speed up the calibration process.

Although the above-mentioned method from MSB to LSB is preferred, it is also practicable and within the scope of the present invention to adopt any other comparison order (e.g., the top-down or the bottom-up manner).

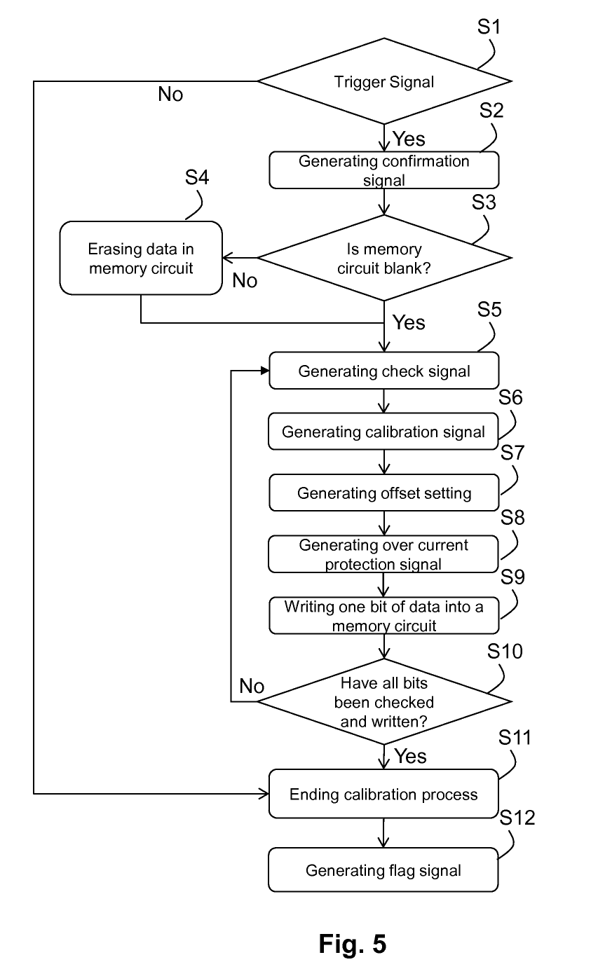

FIG. 5 shows a third embodiment of the present invention, which is a flowchart illustrating a calibration process according to the present invention. As shown in FIG. 5, when the over current protection device receives a trigger signal (step S1), the over current protection device generates a confirmation signal according to any mechanism described above (Step S2), to initiate the calibration process. When the trigger signal does not comply with the mechanism for confirmation, the confirmation signal is not generated, and the calibration process is ended. When the over current protection device enters the calibration process, optionally, it can first confirm whether the memory circuit is blank (step S3). If it is confirmed that the memory circuit is blank, the calibration process goes to step S5. If not, in one embodiment, the calibration process is ended, or in the embodiment as shown in FIG. 5, the data stored in the memory circuit can be erased (step S4). Next, the calibration process generates a check signal (step S5), and a corresponding calibration signal is generated according to the check signal (step S6). In response to the calibration signal, an offset setting is generated (step S7). Next, the calibration process generates an over current protection signal OCP according to the comparison result between the offset setting and the current sensing signal (step S8). According to the status indicated by the over current protection signal OCP, the calibration process writes an appropriate digital number into the memory circuit (step S9). If what is to be stored is a multi-bit digital data, preferably, the multi-bit digital data is written bit by bit, that is, the comparison-and-writing step is performed for one bit, and repeated for a next bit, and for a further next bit, etc. In this case, the calibration process can confirm whether all of the bits have been checked (i.e., the comparison-and-writing step has been repeatedly performed for every bit) (step S10). If there is one or more bits that have not been checked and written, the calibration process returns back to step S5. If all of the bits have been checked and written, the calibration process is ended and a flag signal Flag is generated to indicate that the calibration process is completed.

In one embodiment, the memory circuit includes a writable or a rewritable nonvolatile memory circuit, such as a programmable read only memory (PROM), an erasable programmable read only memory (EPROM), an electrically erasable programmable read only memory (EEPROM), or a flash memory. These memory circuits are well known to those skilled in the art and are therefore not redundantly explained here. Certainly, it is also possible to adopt a volatile memory circuit in the present invention, but this requires to re-set the over current protection threshold in every use.

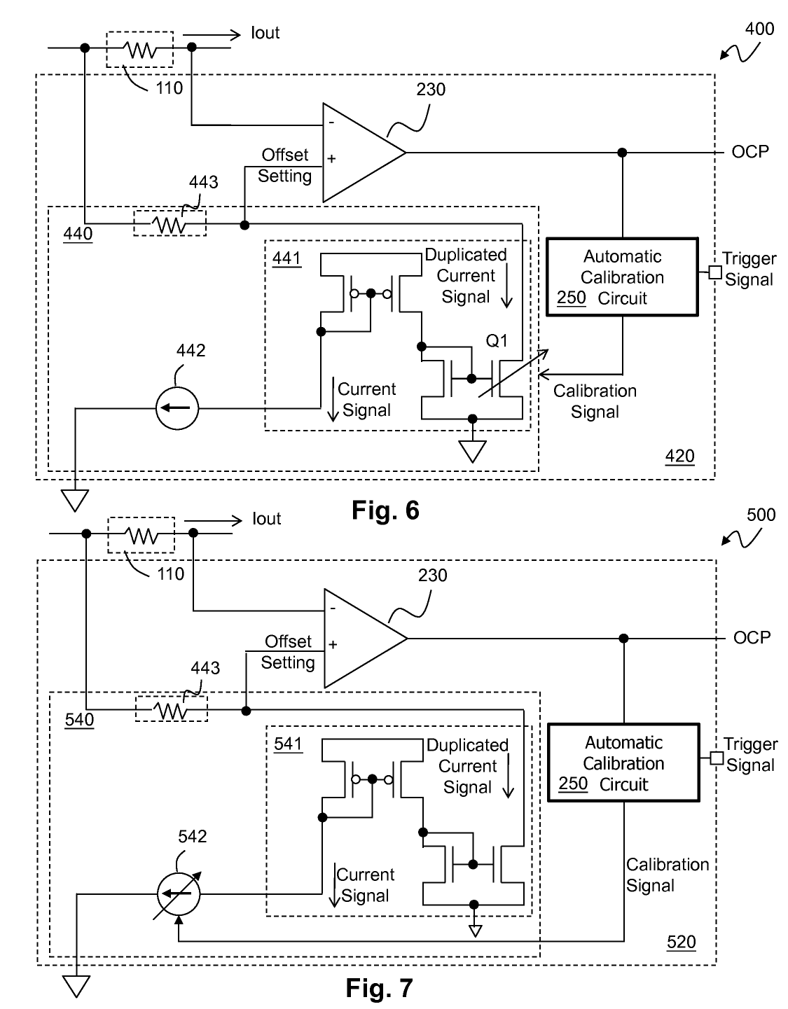

Please refer to FIG. 6, which shows a fourth embodiment of the present invention. As shown in FIG. 6, the protection device 400 comprises a current sensing circuit 110 and a detection circuit 420. The detection circuit 420 comprises an amplifier circuit 230, a setting circuit 440 and an auto calibration circuit 250. This embodiment shows a more specific embodiment of the setting circuit 440, which comprises, for example, a current mirror circuit 441, a current source circuit 442 and a current to voltage conversion circuit 443. The current source circuit 442 generates a current signal, and the current mirror circuit 441 duplicates the current signal to generate a duplicated current signal which is proportional to the current signal. In this embodiment, the setting circuit 440 adjusts the transistor Q1 (such as its size) of the current mirror circuit 441 according to the calibration signal, to adjust the duplication ratio of the current mirror circuit 441, i.e., the ratio between the duplicated current signal and the current signal. The current to voltage conversion circuit 443 can be, for example but not limited to, a resistor, which converts the duplicated current signal to the offset setting. During the calibration process, the offset setting can be fine-tuned to an optimum value by adjusting the duplication ratio of the current mirror circuit 441 according to the calibration signal.

Please refer to FIG. 7, which shows a fifth embodiment of the present invention. As shown in FIG. 7, the protection device 500 comprises a current sensing circuit 110 and a detection circuit 520. The detection circuit 520 comprises an amplifier circuit 230, a setting circuit 540 and an auto calibration circuit 250. This embodiment shows another specific embodiment of the setting circuit 540, which comprises, for example, a current mirror circuit 541, a current source circuit 542 and a current to voltage circuit 443. In this embodiment, the setting circuit 540 adjusts the current level of the current signal generated by the current source circuit 542. The mirror circuit 541 duplicates the current signal to generate a duplicated current signal which is proportional to the current signal. The current to voltage conversion circuit 443 generates the offset setting according to the duplicated current signal. During the calibration process, the offset setting can be fine-tuned to an optimum value by adjusting the current level of the current signal generated by the current source circuit 542 according to the calibration signal.

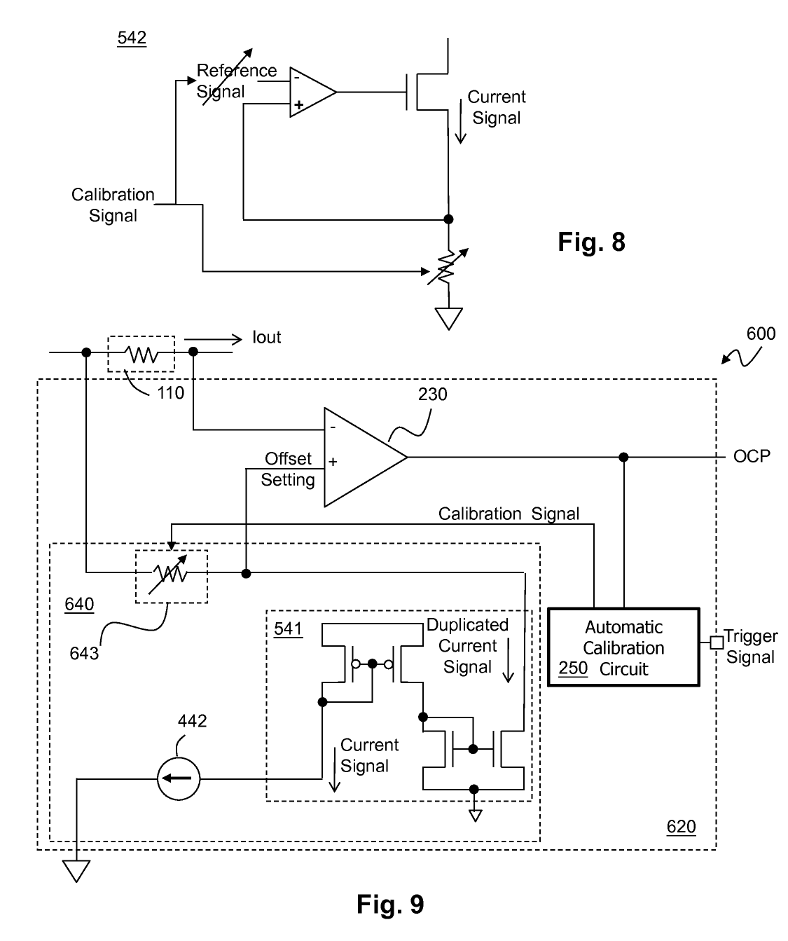

Please refer to FIG. 8, which shows a sixth embodiment of the present invention. This embodiment illustrates an example as to how to adjust the current signal generated by the current source circuit 542. A typical circuit configuration of the current source circuit 542 is as shown in FIG. 8. By adjusting a reference signal or a resistance of a resistor included in the current source circuit 542, the current signal generated by the current source circuit 542 can be correspondingly adjusted.

Please refer to FIG. 9, which shows a seventh embodiment of the present invention. As shown in FIG. 9, the protection device 600 comprises a current sensing circuit 110 and a detection circuit 620. The detection circuit 620 comprises an amplifier circuit 230, a setting circuit 640 and an auto calibration circuit 250. This embodiment shows yet another specific embodiment of the setting circuit 640, which comprises, for example, a current mirror circuit 541, a current source circuit 442 and a current to voltage conversion circuit 643. The current to voltage conversion circuit 643 can be, for example but not limited to, an adjustable resistor, which generates the offset setting according to the duplicated current signal. In this embodiment, the setting circuit 640 can adjust a conversion ratio of the current to voltage conversion circuit 643, to thereby adjust the offset setting.

The above-mentioned embodiments shown in FIGS. 6-9 are not limited to be implemented alone. Two or more of above circuits can be combined in implementation.

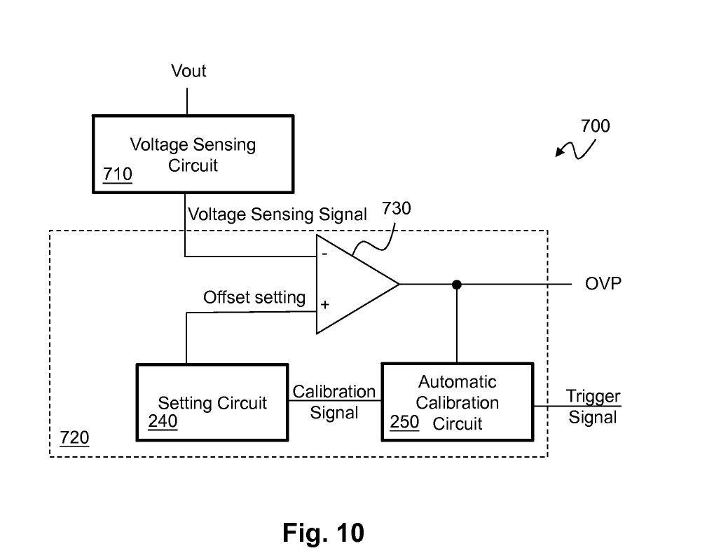

Please refer to FIG. 10, which shows an eighth embodiment of the present invention. This embodiment indicate that the concept of the present invention can be applied not only to over current protection but also to over voltage protection. As shown in FIG. 10, the protection device 700 comprises a voltage sensing circuit 710 and a detection circuit 720. The detection circuit 720 comprises a comparing circuit 730, a setting circuit 240 and an auto calibration circuit 250. The voltage sensing circuit 710 senses a voltage signal Vout and generates a voltage sensing signal corresponding to the voltage signal Vout. The comparing circuit 730 generates an over voltage protection signal OVP according to the voltage sensing signal and an offset setting. The setting circuit 240 is coupled to the comparing circuit 730, for generating the offset setting according to a calibration signal. The automatic calibration circuit 250 is coupled between the comparing circuit 730 and the setting circuit 240, for generating the calibration signal. This embodiment demonstrates that the present invention can also be applied to over voltage protection. Certainly, depending on the desired judgment to be performed, the same circuit can also be applied to other uses such as for under voltage protection, with corresponding amendments of the positive terminal and the negative terminal of the comparing circuit 730 as well as the setting of the corresponding threshold.

To sum up, the applications for the present invention are not limited to the embodiments as shown above. Any application which requires to compare a current/voltage with a threshold by a comparing circuit can adopt the present invention to adjust the threshold.

The present invention has been described in considerable detail with reference to certain preferred embodiments thereof. It should be understood that the description is for illustrative purpose, not for limiting the scope of the present invention. An embodiment or a claim of the present invention does not need to achieve all the objectives or advantages of the present invention. The title and abstract are provided for assisting searches but not for limiting the scope of the present invention. Those skilled in this art can readily conceive variations and modifications within the spirit of the present invention. For example, a device which does not substantially influence the primary function of a signal, such as a switch, can be inserted between any two devices shown to be in direct connection in the embodiments. For another example, the technical meanings represented by the high level and low level of a digital signal are interchangeable, with corresponding amendments of the circuits processing these signals. For yet another example, the positive and negative input terminals of an error amplifier circuit or a comparator are interchangeable, with corresponding amendments of the circuits processing these signals. For still another example, although, in the above-mentioned embodiments, it is demonstrated that the offset setting generated by the setting circuit is inputted to the comparing circuit and compared with the current sensing signal (or the voltage sensing signal), it is equivalent to input a combination of the offset setting with the current sensing signal (e.g., by addition or subtraction) to one terminal of the comparing circuit 230, and to provide a reference signal to the other terminal of the comparing circuit 230. For still another example, the current sensing signal (or the voltage sensing signal) can be multiplied by a ratio such as by using a divider circuit, before it is inputted to the comparing circuit 230. Therefore, the term “current sensing signal (or voltage sensing signal)”, as may be used herein in the specification or claims, should not be limited to referring to a signal directly taken by sensing a current (or a voltage), but can be a signal related to such direct sensing. In view of the foregoing, the spirit of the present invention should cover all such and other modifications and variations, which should be interpreted to fall within the scope of the following claims and their equivalents.

What is claimed is:

1. A protection device, comprising:
a sensing circuit for sensing a current signal or a voltage signal to generate a sensing signal; and
a detection circuit coupled to the sensing circuit, for generating a protection signal according to the sensing signal, the detection circuit including:
a comparing circuit coupled to the sensing circuit, for generating the protection signal according to the sensing signal and an offset setting;
a setting circuit coupled to the comparing circuit, for generating the offset setting according to a calibration signal; and
an automatic calibration circuit coupled between the comparing circuit and the setting circuit, for generating the calibration signal;
wherein during a calibration process, the automatic calibration circuit generates and stores the calibration signal in digital form in correspondence to a protection threshold related to the current signal or the voltage signal, and under a normal operation, the comparing circuit compares the current signal or the voltage signal with the calibrated protection threshold.

2. The protection device of claim 1, wherein the automatic calibration circuit includes:
a control circuit for generating a control signal according to the protection signal during the calibration process;
a digital number generation circuit coupled to the control circuit, for generating a check signal and a write signal according to the control signal, wherein the check signal is used as the calibration signal during the calibration process;
a memory circuit coupled to the digital number generation circuit, for storing the write signal outputted from the digital number generation circuit; and
a multiplexer circuit coupled to the digital number generation circuit and the memory circuit, for selecting the check signal as the calibration signal during the calibration process and selecting a read signal outputted from the memory circuit as the calibration signal under the normal operation.

3. The protection device of claim 1, wherein the setting circuit includes:
a current source circuit for generating a setting current signal;
a current mirror circuit coupled to the current source circuit, for duplicating the setting current signal to a duplicated current signal which is proportional to the setting current signal; and
a current to voltage circuit for converting the duplicated current signal to the offset setting;
wherein the setting current signal is adjustable, or the ratio of the duplicated current signal to the setting current signal is adjustable, or a conversion ratio of the current to voltage circuit is adjustable, or two or more of the above are adjustable.

4. The protection device of claim 2, wherein the setting circuit includes:
a current source circuit for generating a setting current signal;
a current mirror circuit coupled to the current source circuit, for duplicating the setting current signal to a duplicated current signal which is proportional to the current signal; and
a current to voltage circuit for converting the duplicated current signal to the offset setting;
wherein the setting current signal is adjustable, or the ratio of the duplicated current signal to the setting current signal is adjustable, or a conversion ratio of the current to voltage circuit is adjustable, or two or more of the above are adjustable.

5. The protection device of claim 2, wherein the automatic calibration circuit further includes a trigger circuit for receiving a trigger signal and generating a confirmation signal in response to the trigger signal, to initiate the calibration process.

6. The protection device of claim 2, wherein the memory circuit includes a writable or a rewritable nonvolatile memory circuit.

7. A calibration method of a protection device, wherein the protection device is for comparing a signal to be monitored with a protection threshold to generate a judgment signal, the calibration method comprising the steps of:
(1) providing a current signal or a voltage signal which corresponds to the protection threshold;
(2) generating a check signal;
(3) generating a calibration signal according to the check signal and generating an offset setting according to the calibration signal;
(4) generating the judgment signal according to a comparison result between the offset setting and the current signal or the voltage signal; and
(5) writing a digital number into a memory circuit according to a status indicated by the judgment signal.

8. The calibration method of claim 7, further comprising:
generating a flag signal to indicate that the calibration is finished.

9. The calibration method of claim 7, further comprising:
confirming whether the memory circuit is blank before generating the check signal; and
when the memory circuit is not blank, erasing the data stored in the memory circuit.

10. The calibration method of claim 7, further comprising:
repeating the steps (2) to (5) to write multiple digital numbers into the memory circuit, wherein each digital number is one bit of a multi-bit data.

11. The calibration method of claim 10, wherein the multi-bit data is written into the memory circuit from a most significant bit (MSB) to a least significant bit (LSB).

12. The calibration method of claim 7, further comprising:
before generating the check signal, confirming that a calibration process is initiated according to a trigger signal.

13. The calibration method of claim 12, wherein the step of confirming that a calibration process is initiated according to the trigger signal includes:
confirming whether the calibration process is initiated according to a level of the trigger signal or according to whether the trigger signal lasts for a predetermined time period.
